(19) United States
(12) Patent Application Publication
(10) Pub. No.: US 2023/0276630 A1
(43) Pub. Date: Aug. 31, 2023

(54) SEMICONDUCTOR DEVICE

(71) Applicant: Kioxia Corporation, Tokyo (JP)

(72) Inventor: Tetsu MOROOKA, Yokkaichi Mie (JP)

(73) Assignee: Kioxia Corporation, Minato-ku, Tokyo (JP)

(21) Appl. No.: 17/900,042

(22) Filed: Aug. 31, 2022

(30) Foreign Application Priority Data
Feb. 28, 2022 (JP) 2022-028862

(51) Int. Cl. H01L 27/11573; H01L 27/1157; H01L 27/11531

(52) U.S. Cl. CPC H01L 27/11573; H01L 27/1157; H01L 27/11531

(57) ABSTRACT

A semiconductor device includes: a plurality of first interconnections extending in a first direction and spaced from one another in a second direction crossing the first direction; a channel adjacent to the first interconnections in a third direction crossing the first direction and the second direction and extending in the second direction; and a plurality of first charge storage sections, each of the first charge storage sections provided between a corresponding one of the first interconnections and the channel. The first interconnections each include a first portion relatively farther from the channel and a second portion relatively closer to the channel, wherein the first portion includes a first thickness in the second direction and the second portion includes a second thickness in the second direction, and wherein the second thickness is substantially greater than the first thickness.

### CROSS-REFERENCE TO RELATED APPLICATION(S)

This application is based upon and claims the benefit of priority from Japanese Patent Application No. 2022-028862, filed Feb. 28, 2022, the entire contents of which are incorporated herein by reference.

### FIELD

Embodiments described herein relate generally to a semiconductor device.

### BACKGROUND

A semiconductor storage device having a stacked body in which insulating films and word lines are alternately stacked and semiconductor pillars that penetrate this stacked body has been proposed. In general, it is expected that the semiconductor storage device can achieve further improved electrical characteristics.

### DESCRIPTION OF THE DRAWINGS

FIG. 1 is a perspective view illustrating configurations of a semiconductor device according to an embodiment.

FIG. 2 is a cross-sectional view, which is taken along line F2-F2, of a stacked body illustrated in FIG. 1.

FIG. 3 is a cross-sectional view, which is taken along line F3-F3, of the stacked body illustrated in FIG. 2.

FIGS. 4A to 4D are cross-sectional views illustrating part of a process of manufacturing the semiconductor device according to the embodiment.

FIGS. 5A to 5D are cross-sectional views, subsequent to FIG. 4D, illustrating part of the process of manufacturing the semiconductor device according to the embodiment.

FIGS. 6A and 6B are cross-sectional views, subsequent to FIG. 5D, illustrating part of the process of manufacturing the semiconductor device according to the embodiment.

FIG. 7 is a cross-sectional view illustrating a semiconductor device according to a comparative example.

### DETAILED DESCRIPTION

Embodiments provide a semiconductor device capable of improving write-erase characteristics.

In general, according to one embodiment, a semiconductor device includes: a plurality of first interconnections extending in a first direction and spaced from one another in a second direction crossing the first direction; a channel adjacent to the first interconnections in a third direction crossing the first direction and the second direction and extending in the second direction; and a plurality of first charge storage sections, each of the first charge storage sections provided between a corresponding one of the first interconnections and the channel. The first interconnections each include a first portion relatively farther from the channel and a second portion relatively closer to the channel, wherein the first portion includes a first thickness in the second direction and the second portion includes a second thickness in the second direction, and wherein the second thickness is substantially greater than the first thickness.

Hereinafter, an embodiment of the disclosure will be described with reference to the drawings. In illustrations of the drawings to be described hereinafter, same or similar elements are denoted by same or similar reference signs. It is noted that the drawings are schematic illustrations, and relations between thickness and planar dimensions and the like may differ from those of actual elements.

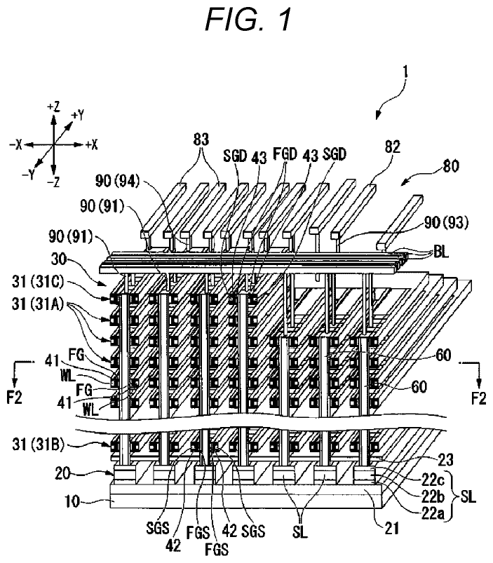

First, configurations of a semiconductor device 1 according to the present embodiment will be described with reference to FIG. 1. FIG. 1 is a perspective view illustrating the configurations of the semiconductor device 1. The semiconductor device 1 is a non-volatile semiconductor storage device, and, for example, a NAND flash memory.

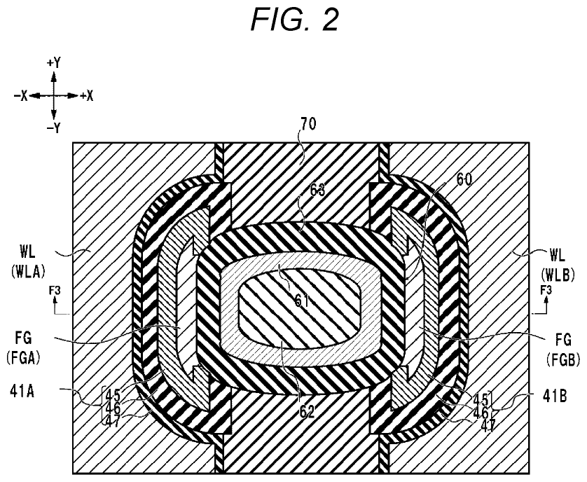

As illustrated in FIG. 1, the semiconductor device 1 includes, for example, a silicon substrate 10, a lower structure 20, a stacked body 30, a plurality of pillars (columnar bodies) 60, an insulation isolating section 70 (refer to FIG. 2), an upper structure 80, and a plurality of contacts 90. FIG. 1 schematically illustrates the pillars 60 as square pillars.

Subsequently, a +X direction, a −X direction, a +Y direction, a −Y direction, a +Z direction, and a −Z direction will be defined. The +X direction, the −X direction, the +Y direction, and the −Y direction are directions along a surface of the silicon substrate 10. The +X direction is a direction in which bit lines BL, to be described later, extend. The −X direction is an opposite direction to the +X direction. When being not distinguished, the +X direction and the −X direction are simply referred to as “X direction”. The +Y direction and the −Y direction are directions crossing, e.g., orthogonal to the X direction. The +Y direction is a direction in which word lines WL, to be described later, extend. The −Y direction is an opposite direction to the +Y direction. When being not distinguished, the +Y direction and the −Y direction are simply referred to as “Y direction”. The +Z direction and the −Z direction are directions crossing, e.g., orthogonal to the X direction and the Y direction and a thickness direction of the silicon substrate 10. The +Z direction is a direction from the silicon substrate 10 to the stacked body 30 to be described later. The −Z direction is an opposite direction to the +Z direction. When being not distinguished, the +Z direction and the −Z direction are simply referred to as “Z direction”. In the present specification, the “+Z direction” and the “−Z direction” are often referred to as “upper” and “lower”, respectively. It is noted that these expressions are only for convenience of description and do not specify a gravitational direction. The Y direction is an example of a “first direction”. The X direction is an example of a “second direction”. The Z direction is an example of a “third direction”.

The silicon substrate 10 is a substrate that serves as a base of the semiconductor device 1. At least part of the surface of the silicon substrate 10 is formed into a plate shape along the X direction and the Y direction. The silicon substrate 10 is formed using, for example, a semiconductor material containing silicon (Si).

The lower structure 20 is provided on the silicon substrate 10. The lower structure 20 includes, for example, a lower insulating film 21, a plurality of source lines SL, and an upper insulating film 23. The lower insulating film 21 is provided on the silicon substrate 10. The plurality of source lines SL are provided on the lower insulating film 21. At least two source lines SL among the plurality of source lines SL are adjacent in the X direction. In addition, the plurality of source lines SL extend in the Y direction. Each source line SL includes, for example, a conductive layer 22a provided on the lower insulating film 21, an interconnection layer 22b provided on the conductive layer 22a, and a conductive layer 22c provided on the interconnection layer 22b. The upper insulating film 23 is provided above the plurality of source lines SL. An insulating member, not illustrated, is provided between the adjacent source lines SL, between the source lines SL and the upper insulating film 23, and between the lower insulating film 21 and the upper insulating film 23.

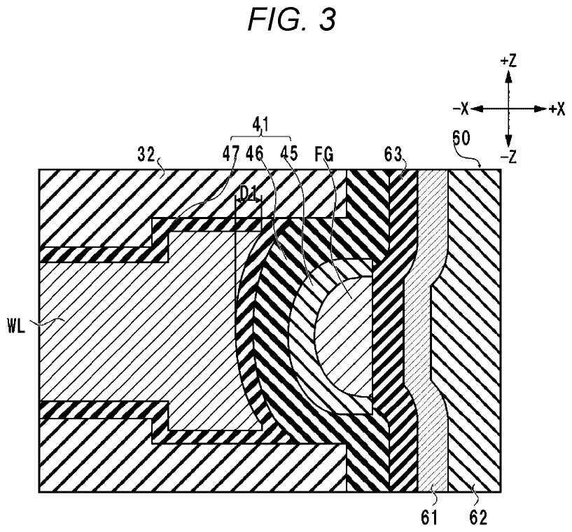

The stacked body 30 is provided on the lower structure 20. The stacked body 30 includes, for example, a plurality of functional layers 31 and a plurality of interlayer insulating films 32 (refer to FIG. 3). The plurality of functional layers 31 and the plurality of insulating films 32 are alternately stacked in the Z direction one layer by one layer. Some of the plurality of functional layers 31 are a plurality of first functional layers 31A. At least another one of the plurality of functional layers 31 is a second functional layer 31B. At least yet another one of the plurality of functional layers 31 is a third functional layer 31C.

Each of the plurality of first functional layers 31A includes, for example, a plurality of word lines WL, a plurality of floating gate electrodes FG, and a plurality of block insulating films 41. The plurality of word lines WL are interconnections provided sideways of the pillars 60. At least two word lines WL provided in one first functional layer 31A among the plurality of word lines WL are adjacent in the X direction and extend in the Y direction. A voltage is applied to each word line WL from a drive circuit, not illustrated, when electrons are injected into one floating gate electrode FG, to be described later, or when electrons injected into the floating gate electrode FG are extracted from the floating gate electrode FG. As a result of application of the voltage to the word line WL, a predetermined electric field is applied to the floating gate electrode FG.

Each of the plurality of floating gate electrodes FG is an electrode film provided sideways of each pillar 60. The floating gate electrode FG is a film capable of storing electric charges. A storage state of the electrons stored in the floating gate electrode FG changes when the voltage is applied to the word line WL. Each floating gate electrode FG is provided between the word line WL to which the floating gate electrode FG corresponds and the pillar 60 to which the floating gate electrode FG corresponds. In the present specification, “correspond” means, for example, that two elements are combined to configure one memory cell.

Each of the plurality of block insulating films 41 is provided between the word line WL to which the block insulating film 41 corresponds and the floating gate electrode FG to which the block insulating film 41 corresponds. Details of these first functional layers 31A will be described later.

The second functional layer 31B is provided below the plurality of first functional layers 31A. The second functional layer 31B includes, for example, a plurality of source-side select gate lines SGS, a plurality of source-side select gate electrodes FGS, and a plurality of block insulating films 42. At least two source-side select gate lines SGS among the plurality of source-side select gate lines SGS are adjacent in the X direction and extend in the Y direction. Each of the plurality of source-side select gate electrodes FGS is provided between the source-side select gate line SGS to which the source-side select gate electrode FGS corresponds and the pillar 60 to which the source-side select gate electrode FGS corresponds. Each of the plurality of block insulating films 42 is provided between the source-side select gate line SGS to which the block insulating film 42 corresponds and the source-side select gate electrode FGS to which the block insulating film 42 corresponds. A voltage is applied to one source-side select gate line SGS from the drive circuit, not illustrated, when conduction is allowed between the pillar 60 and the source line SL. As a result of application of the voltage to the source-side select gate line SGS, a predetermined electric field is applied to the source-side select gate electrode FGS.

The third functional layer 31C is provided above the plurality of first functional layers 31A. The third functional layer 31C includes, for example, a plurality of drain-side select gate lines SGD, a plurality of drain-side select gate electrodes FGD, and a plurality of block insulating films 43. At least two drain-side select gate lines SGD among the plurality of drain-side select gate lines SGD are adjacent in the X direction and extend in the Y direction. Each of the plurality of drain-side select gate electrodes FGD is provided between the word line WL to which the drain-side select gate electrode FGD corresponds and the pillar 60 to which to which the drain-side select gate electrode FGD corresponds. Each of the plurality of block insulating films 43 is provided between the drain-side select gate line SGD to which the block insulating film 43 corresponds and the drain-side select gate electrode FGD to which the block insulating film 43 corresponds. A voltage is applied to the drain-side select gate line SGD from the drive circuit, not illustrated, when conduction is allowed between the pillar 60 and the source line SL. As a result of application of the voltage to the drain-side select gate line SGD, a predetermined electric field is applied to the drain-side select gate electrode FGD.

At least one of the plurality of pillars 60 is provided on at least one source line SL and extends in the Z direction. The plurality of pillars 60 are provided apart from one another in the X direction and the Y direction. For example, in a view from the Z direction, the plurality of pillars 60 are arrayed in a matrix along the X direction and the Y direction. A lower end of each pillar 60 penetrates the upper insulating film 23 of the lower structure 20 and is connected to at least one source line SL among the plurality of source lines SL. Details of the pillars 60 will be described later.

The upper structure 80 is provided on the stacked body 30. The upper structure 80 includes, for example, a plurality of bit lines BL, interconnections 81, not illustrated, for the source-side select gate lines SGS, interconnections 82 for the word lines WL, and interconnections 83 for the drain-side select gate lines SGD.

The plurality of contacts 90 extend in the Z direction. At least one of the plurality of contacts 90 is, for example, a contact 91 for each pillar 60. At least another one of the plurality of contacts 90 is a contact 92, not illustrated, for each source-side select gate line SGS. At least yet another one of the plurality of contacts 90 is a contact 93 for each word line WL. At least still another one of the plurality of contacts 90 is a contact 94 for each drain-side select gate line SGD.

The contact 91 is provided on one pillar 60. At least two bit lines BL among the plurality of bit lines BL are adjacent in the Y direction and extend in the X direction. One of the adjacent pillars 60 among the plurality of pillars 60 arrayed in the X direction is connected to one bit line BL among the bit lines BL, while the other pillar 60 is connected to the other bit line BL.

At least one of a plurality of contacts 92, not illustrated, is provided on a +Y-direction end portion of at least one source-side select gate line SGS. At least one of the interconnections 81, not illustrated, is provided on at least one contact 92 and extends in the Y direction. Any of the interconnections 81 is connected to any of the source-side select gate lines SGS via any of the contacts 92.

At least one of a plurality of contacts 93 is provided on a Y-direction end portion of at least one word line WL. At least one of the interconnections 82 is provided on at least one contact 93 and extends in the Y direction. Any of the interconnections 82 is connected to any of the word lines WL via any of the contacts 93.

At least one of a plurality of contacts 94 is provided on a +Y-direction end portion of at least one drain-side select gate line SGD. At least one of the interconnections 83 is provided on at least one contact 94 and extends in the Y direction. Any of the interconnections 83 is connected to any of the drain-side select gate line SGD via any of the contacts 94.

Next, a structure of the stacked body 30 will be described in detail with reference to FIGS. 2 and 3. FIG. 2 is a cross-sectional view, which is taken along line F2-F2, of the stacked body 30 illustrated in FIG. 1. FIG. 3 is a cross-sectional view, which is taken along line F3-F3, of the stacked body 30 illustrated in FIG. 2.

The stacked body 30 has a storage structure that can store information around each pillar 60. Specifically, as illustrated in FIG. 2, the storage structures are provided around the pillars 60 and face each other in the X direction. In addition, the storage structures provided around the plurality of pillars 60 are identical in structure.

First, the word lines WL will be described. As illustrated in FIG. 2, one of a plurality of word lines WL is a first word line WLA located on an −X direction-side of each pillar 60, and the other word line WL is a second word line WLB located on a +X direction-side of the pillar 60. The first word line WLA and the second word line WLB are adjacent in the X direction and extend in the Y direction. The first word line WLA and the second word line WLB are led out in the opposite directions in, for example, the Y direction and controlled independently of each other. Each word line WL has a shape, for example, such that a part near the floating gate electrode FG, to be described later, (a peripheral region including a surface of the word line WL on which the word line WL is closest to the floating gate electrode FG) protrudes vertically, as illustrated in FIG. 3. That is, the word line WL has the shape of being thicker in the Z direction. Furthermore, a surface of the word line WL facing the pillar 60 is desirably a curved shape recessed to the word line WL. A depth Dl of a recess in a curved surface formed in the word line WL illustrated in FIG. 3 is at least equal to or larger than 5 nm. More specifically, it is desirable that the depth Dl is approximately 10 nm. The curved surface recessed to the word line WL is intended to increase a surface area of the block insulating film 41. Owing to this, when the depth Dl is smaller than 5 nm, an effect of increasing the surface area is likely to be insufficient. On the other hand, when the depth Dl is excessively large, disadvantages occur that the floating gate electrode FG becomes thicker to enlarge a cell size and a Vth fluctuation becomes greater due to an interference between adjacent cells.

The first word line WLA is an example of a “first interconnection”. The second word line WLB is an example of a “second interconnection”.

Each word line WL is formed using, for example, tungsten. A barrier metal film, not illustrated, preventing diffusion of a material of the word line WL may be provided on a surface of the word line WL. The barrier metal film is formed using, for example, titanium nitride (TiN).

The floating gate electrodes FG will next be described. As illustrated in FIG. 2, one of the plurality of floating gate electrodes FG is a first floating gate electrode FGA located on the −X direction-side of each pillar 60, and the other floating gate electrode FG is a second floating gate electrode FGB located on the +X direction-side of the pillar 60. The first floating gate electrode FGA is provided between the first word line WLA and the pillar 60. Meanwhile, the second floating gate electrode FGB is provided between the second word line WLB and the pillar 60. The plurality of floating gate electrodes FG are each surrounded by the block insulating film 41 and a tunnel insulating film 63 to be described later, as illustrated in, for example, FIG. 3. Furthermore, a surface of each of the plurality of floating gate electrodes FG in contact with the block insulating film 41 has a curved shape protruding toward the word line WL. The first floating gate electrode FGA is an example of a “first charge storage section”. The second floating gate electrode FGB is an example of a “second charge storage section”.

The floating gate electrodes FG are formed using, for example, polysilicon. A storage state of electrons stored in the first floating gate electrode FGA changes when a voltage is applied to the first floating gate electrode FGA from the first word line WLA. A storage state of electrons stored in the second floating gate electrode FGB changes when an electric field is applied to the second floating gate electrode FGB from the second word line WLB.

The block insulating films 41 will next be described. As illustrated in FIG. 2, one of the plurality of block insulating films 41 is a first block insulating film 41A located on the −X direction-side of each pillar 60, and the other block insulating film 41 is a second block insulating film 41B located on the +X direction-side of the pillar 60. The first block insulating film 41A is provided between the first word line WLA and the first floating gate electrode FGA. The second block insulating film 41B is provided between the second word line WLB and the second floating gate electrode FGB.

Each of the first and second block insulating films 41A and 41B is formed using, for example, three insulating films 45, 46, and 47.

The insulating film 45 is located closest to the floating gate electrode FG among the three insulating films 45, 46, and 47. The insulating film 45 covers a word line WL-side surface of the floating gate electrode FG as illustrated in, for example, FIG. 3. The insulating film 45 is formed using, for example, a High-k material such as a silicon nitride (SiN) or a hafnium oxide (HfO). Alternatively, the insulating film 45 may be formed using a material containing ruthenium (Ru), aluminum (Al), titanium (Ti), Zirconium (Zr), or silicon (Si).

The insulating film 46 is provided opposite to the floating gate electrode FG across the insulating film 45. The insulating film 46 covers the word line WL-side surface of the floating gate electrode FG via the insulating film 45, as illustrated in, for example, FIG. 3. The insulating film 46 is formed using, for example, a silicon oxide film.

The insulating film 47 is provided opposite to the floating gate electrode FG across the insulating films 45 and 46. The insulating film 47 is provided along a boundary between the insulating film (interlayer insulating film) 32 and the word line WL, and covers the word line WL-side surface of the floating gate electrode FG via the insulating films 45 and 46, as illustrated in, for example, FIG. 3. The insulating film 47 is formed using, for example, a High-k film that is an oxide film containing a high dielectric constant material such as aluminum (Al), hafnium (Hf), or zirconium (Zr). The insulating film 47 may be formed using a silicon nitride film.

The pillars 60 will next be described. As illustrated in FIG. 2, each pillar 60 is provided between the first word line WLA and the second word line WLB. The pillar 60 includes, for example, a channel 61, a core insulating section 62, and the tunnel insulating film 63.

The channel 61 extends in the Z direction over an entire length (entire height) of the pillar 60 in the Z direction. The channel 61 penetrates the upper insulating film 23 of the lower structure 20 and a lower end of the channel 61 is connected to one source line SL. Meanwhile, an upper end of the channel 61 is connected to one bit line BL via one contact 91. The channel 61 is formed using a semiconductor material such as polysilicon (Poly-Si). The channel 61 may be formed using, for example, polysilicon partially doped with an impurity. The impurity contained in the channel 61 is at least one of a group consisting of, for example, carbon, phosphorus, boron, and germanium. A current is applied to the channel 61 between the source line SL and the bit line BL when, for example, electrons are injected into the floating gate electrode FG or electrons injected into the floating gate electrode FG are extracted from the floating gate electrode FG. In the present embodiment, the channel 61 is formed annularly between the first word line WLA and the second word line WLB.

The core insulating section 62 is provided closer to a center side of the pillar 60 than the channel 61 in the X direction and the Y direction. The core insulating section 62 is provided, for example, on an inner circumference of the channel 61. The core insulating section 62 extends in the Z direction over the entire length (entire height) of the pillar 60 in the Z direction. The core insulating section 62 is formed using, for example, a silicon oxide (SiO).

The tunnel insulating film 63 is provided at least along a −X direction-side surface and a +X direction-side surface of the channel 61. The tunnel insulating film 63 extends in the Z direction, for example, over the entire length (entire height) of the pillar 60 in the Z direction.

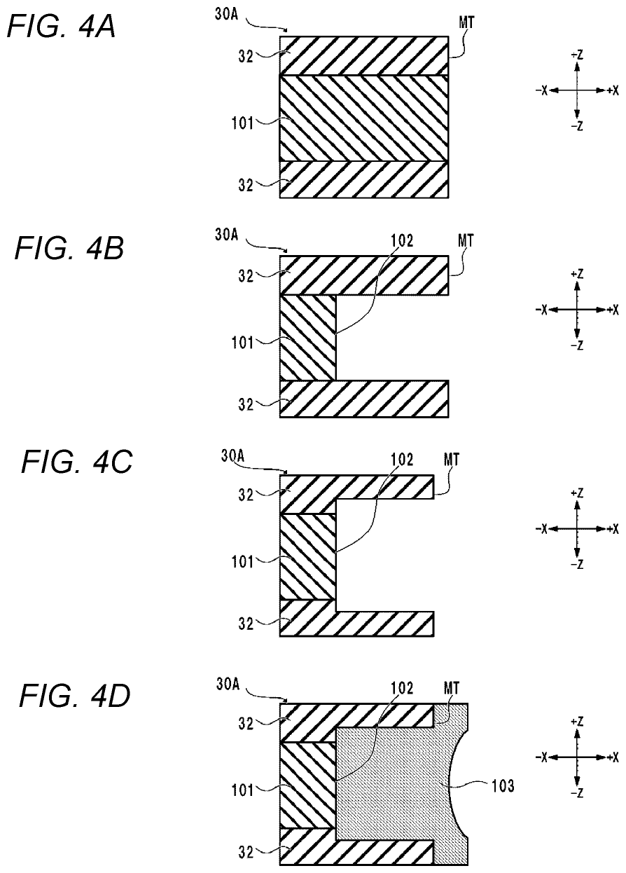

Next, a method of manufacturing the semiconductor device 1 will be described. FIGS. 4A to 6B are cross-sectional views illustrating part of a process of manufacturing the semiconductor device 1. FIGS. 4A to 6B illustrate the process of forming the stacked body 30 in the same cross-section as that illustrated in FIG. 3.

First, a plurality of sacrificial films 101 and a plurality of interlayer insulating films 32 are alternately stacked to form an intermediate stacked body 30A. The sacrificial films 101 are layers replaced by the word lines WL in a later process. The sacrificial films 101 are formed using, for example, a silicon nitride. The interlayer insulating films 32 are formed using, for example, a silicon oxide (SiO). Next, a mask, not illustrated, is provided above the intermediate stacked body 30A and a memory cell trench MT is formed by, for example, etching. The memory cell trench M is a recess penetrating the plurality of sacrificial films 101 and the plurality of insulating films 32 in the Z direction. FIG. 4A illustrates a state of extracting one layer of the intermediate stacked body 32A.

Next, as illustrated in FIG. 4B, the sacrificial film 101 is etched via the memory cell trench MT. As a result, part of the sacrificial film 101 exposed to the memory cell trench MT is removed and a recess 102 is formed on side surfaces of the memory cell trench MT.

Next, as illustrated in FIG. 4C, the interlayer insulating films 32 are etched via the memory cell trench MT. As a result, part of each interlayer insulating film 32 exposed to the memory cell trench MT is removed. As such, the recess 102 on the side surfaces of the memory cell trench MT becomes longer in the Z direction.

Next, as illustrated in FIG. 4D, an intermediate (generation) film 103 is formed on an inside surface of the memory cell trench MT and an inside surface of the recess 102. The intermediate generation film 103 is formed using, for example, a silicon nitride (SiN). At this time, the intermediate generation film 103 formed in the recess 102 has a curved shape recessed in a direction of the recess 102.

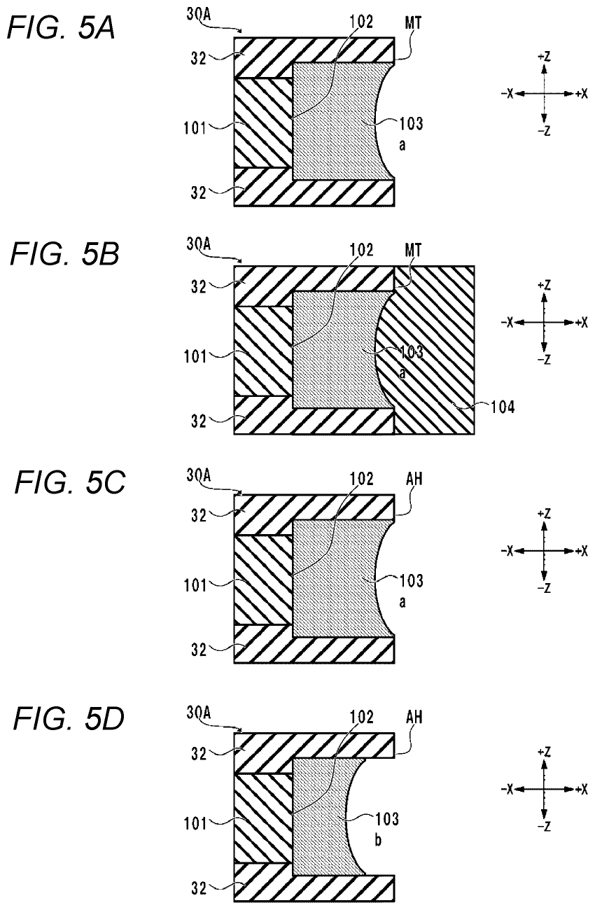

Next, as illustrated in FIG. 5A, the intermediate generation film 103 is etched via the memory cell trench MT. As a result, a residual section 103a having a curved shape recessed in the direction of the recess 102 is formed in the recess 102.

Next, as illustrated in FIG. 5B, an intermediate insulating layer 104 is formed in the memory cell trench MT. The intermediate insulating layer 104 is formed using, for example, a silicon oxide (SiO).

Next, as illustrated in FIG. 5C, a mask, not illustrate, corresponding to the pillar 60 is provided above the intermediate stacked body 30A and a memory hole AH is formed by, for example, etching. The memory hole AH is a hole penetrating the intermediate insulating layer 104 in the Z direction and reaches the source line SL.

Next, as illustrated in FIG. 5D, the residual section 103a is etched via the memory hole AH. As a result, a surface of the residual section 103a is removed and a residual section 103b is formed with a position of the curved shape moved in the direction of the recess 102.

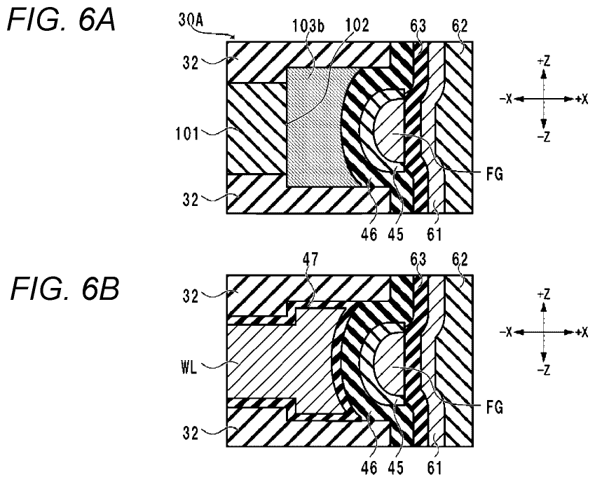

Next, as illustrated in FIG. 6A, the insulating films 45 and 46, the floating gate electrode FG, the tunnel insulating film 63, the channel 61, and the core insulating section 62 are formed in the memory hole AH. As a result, most of the storage structure and the pillar 60 are formed.

Next, etching is performed via another trench, not illustrated, provided in the intermediate stacked body 30A to remove the plurality of sacrificial films 101 and the residual sections 103b. The insulating films 47 and the word lines WL are formed alternately in a space formed by removing the sacrificial films 101 and the residual section 103b. The contacts 91 to 94, the interconnections 81 to 83, and the like are then formed. Thus, the semiconductor device 1 is completed.

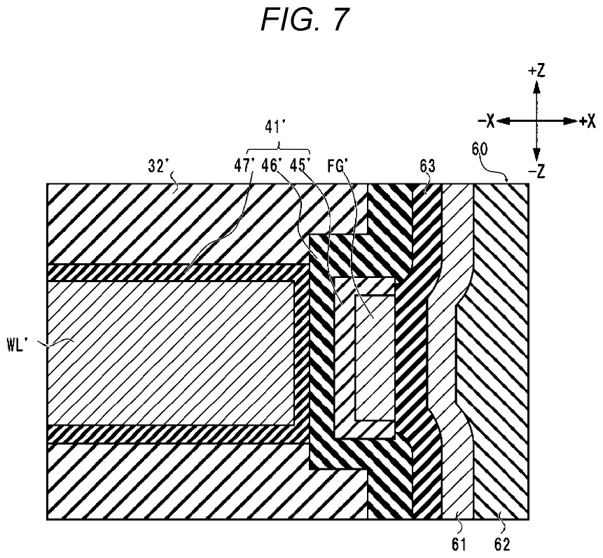

Advantages of the semiconductor device 1 according to the present embodiment will be described using a comparative example. FIG. 7 is a cross-sectional view illustrating a storage structure of a semiconductor device according to the comparative example. Elements configuring the storage structure are similar to those in the semiconductor device 1 according to the present embodiment and denoted by the same reference signs. It is noted that elements different in shape are distinguished by adding “′” to each reference sign.

The semiconductor device according to the comparative example differs from the semiconductor device 1 according to the present embodiment in the following respects. Insulating films 45′ and 46′ linearly cover three surfaces of a floating gate electrode FG′ except for a surface of the floating gate electrode FG′ that contacts the pillar 60. In addition, pillar 60-side surfaces of an insulating film 47′ and a word line WL′ are flat. In other words, the semiconductor device according to the comparative example differs from the semiconductor device 1 according to the present embodiment in that the insulating films 45′, 46′, and 47′ of a block insulating film 41, the floating gate electrode FG′, and the word line WL′ do not have the curved shape. The semiconductor device according to the comparative example also differs from the semiconductor device 1 according to the present embodiment in that a part of the word line WL′ close to the floating gate electrode FG′ does not have the shape protruding in the +Z direction and the −Z direction.

Providing the storage structure of the semiconductor device 1 according to the present embodiment enables an increase in an area of surfaces on which the floating gate electrode FG contacts the insulating film 45. This can increase a capacity of each block insulating film with respect to each tunnel insulating film; therefore, it is possible to strengthen an electric field of the tunnel insulating film and weaken an electric field of the block insulating film. As a result, it is possible to improve write-erase characteristics.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a plurality of first interconnections extending in a first direction and spaced from one another in a second direction crossing the first direction;
a channel adjacent to the first interconnections in a third direction crossing the first direction and the second direction and extending in the second direction;
and
a plurality of first charge storage sections, each of the first charge storage sections provided between a corresponding one of the first interconnections and the channel, wherein the first interconnections each include a first portion relatively farther from the channel and a second portion relatively closer to the channel, wherein the first portion includes a first thickness in the second direction and the second portion includes a second thickness in the second direction, and wherein the second thickness is substantially greater than the first thickness.

2. The semiconductor device according to claim 1, further comprising:
a plurality of second interconnections extending in the first direction and spaced from one another in the second direction, the plurality of second interconnections disposed adjacent to the channel; and
a plurality of second charge storage sections, each of the second charge storage sections provided between a corresponding one of the second interconnections and the channel, wherein
the fourth interconnections each include a third portion relatively farther from the channel and a fourth portion relatively closer to the channel, wherein the third portion includes a third thickness in the second direction and the fourth portion includes a fourth thickness in the second direction, and wherein the fourth thickness is substantially greater than the third thickness.

3. The semiconductor device according to claim 1, wherein
the first charge storage sections each have a curved shape protruding toward the first interconnections.

4. The semiconductor device according to claim 1, wherein
each of the first interconnections adjacent to the corresponding first charge storage section has a curved surface recessed toward the first interconnections.

5. The semiconductor device according to claim 4, wherein
the curved surface of each of the first interconnections has a depth equal to or greater than 5 nm.

6. The semiconductor device according to claim 4, wherein
the curved surface of each of the first interconnections has a depth equal to 10 nm.

7. The semiconductor device according to claim 1, further comprising:
a third interconnect extending in the third direction and connected to a first end of the channel; and
a fourth interconnect extending in the first direction and connected to a second end of the channel.

8. The semiconductor device according to claim 1, wherein the channel extends through the plurality of first interconnections.

9. The semiconductor device according to claim 2, wherein the plurality of first interconnections and the plurality of second interconnections are coupled to opposite ends of the channel in the third direction, respectively.

10. The semiconductor device according to claim 9, wherein the channel surrounds an insulating core extending in the second direction.

11. A method for fabricating semiconductor devices, comprising:
etching a portion of a sacrificial film interposed between a first insulating film and a second insulating film to form a recess;
extending the recess in a vertical direction by removing respective portions of the first insulating film and the second insulating film;
filling the recess with an intermediate film;
etching a portion of the intermediate film to re-expose a portion of the recess; and
replacing a remaining portion of the intermediate film and the sacrificial film with an interconnection.

12. The method according to claim 11, further comprising:
forming a charge storage section in the re-exposed portion of the recess; and
forming a semiconductor channel extending in the vertical direction.

13. The method according to claim 12, wherein the interconnection extends in a first lateral direction, and wherein the charge storage section is interposed between the semiconductor channel and the interconnection in a second lateral direction.
